(19) United States
(12) Patent Application Publication
(10) Pub. No.: US 2026/0123537 A1
(43) Pub. Date: Apr. 30, 2026

(54) SEMICONDUCTOR PACKAGE AND MANUFACTURING METHOD THEREOF

(71) Applicant: SK hynix Inc., Gyeonggi-do (KR)

(72) Inventors: Heon Yong CHANG, Gyeonggi-do (KR); Young Hun CHEONG, Gyeonggi-do (KR)

(21) Appl. No.: 19/066,166

(22) Filed: Feb. 28, 2025

(30) Foreign Application Priority Data
Oct. 31, 2024 (KR) 10-2024-0152115

(51) Int. Cl. H01L 23/00; H01L 23/31; H01L 23/538; H01L 25/07

(52) U.S. Cl. CPC H10W 90/00; H10W 70/60; H10W 70/611; H10W 72/535; H10W 72/543; H10W 74/111; H10W 90/24; H10W 90/754

(57) ABSTRACT

A semiconductor package may include a semiconductor chip; a bonding wire having one end that contacts an upper surface of the semiconductor chip; a landing pad contacting the other end of the bonding wire, and facing the upper surface of the semiconductor chip; a coating layer disposed between the landing pad and the semiconductor chip, surrounding a side surface of the bonding wire, and including a hole; and an encapsulation layer surrounding the coating layer.

### CROSS-REFERENCE TO RELATED APPLICATION

The present application claims priority under 35 U.S.C. § 119(a) to Korean Patent Application No. 10-2024-0152115 filed on Oct. 31, 2024, which is incorporated herein by reference in its entirety.

### BACKGROUND

### 1. Technical Field

Embodiments of the present disclosure relate generally to semiconductor technology and, more particularly to a semiconductor package and a method for manufacturing the same.

### 2. Related Art

Semiconductor devices are attracting attention as an important element in the electronics industry due to their characteristics such as miniaturization, multi-functionality and/or low manufacturing cost. As the electronics industry advances, semiconductor devices are becoming increasingly highly integrated. In order to achieve high integration of semiconductor devices, a method of stacking semiconductor chips is being used. When stacking semiconductor chips, the technology of forming input/output wirings on the semiconductor chips faces various technical limitations.

### SUMMARY

Various embodiments of the present disclosure are directed to providing a semiconductor package and a method for manufacturing the same capable of improving electrical connection characteristics between a semiconductor chip and an outside of the semiconductor chip.

In an embodiment of the present disclosure, a semiconductor package may include a semiconductor chip; a bonding wire having one end that contacts an upper surface of the semiconductor chip; a landing pad contacting the other end of the bonding wire, and facing the upper surface of the semiconductor chip; a coating layer disposed between the landing pad and the semiconductor chip, surrounding a side surface of the bonding wire, and including a hole; and an encapsulation layer surrounding the coating layer.

In an embodiment of the present disclosure, a semiconductor package may include a first semiconductor chip and a second semiconductor chip; a first bonding wire connected to the first semiconductor chip; a second bonding wire connected to the second semiconductor chip; a first coating layer surrounding a side surface of the first bonding wire, and including a first hole; a second coating layer surrounding a side surface of the second bonding wire, including a second hole, and spaced apart from the first coating layer; and an encapsulation layer surrounding the first coating layer and the second coating layer, and filling interiors of the first hole and the second hole.

In an embodiment of the present disclosure, a method for manufacturing a semiconductor package may include connecting one end of a bonding wire to a semiconductor chip, and aligning the bonding wire in a direction perpendicular to an upper surface of the semiconductor chip; forming a coating layer that surrounds a side surface of the bonding wire and includes a hole; and forming an encapsulation layer to surround a side surface of the coating layer and fill an interior of the hole.

According to the embodiments of the present disclosure, it is possible to improve electrical connection characteristics between a semiconductor chip and an outside of the semiconductor chip.

These and other features and embodiments of the present disclosure will become apparent to those with ordinary skill in the art from the following description of embodiments in connection with the accompanying drawings.

### BRIEF DESCRIPTION OF THE DRAWINGS

FIG. 1 is a view illustrating a cross-sectional structure of a semiconductor package according to embodiments of the present disclosure.

FIG. 2 is an enlarged view of a part 10 of FIG. 1.

FIG. 3 and FIG. 4 are views each illustrating the three-dimensional structure and planar structure of a part of FIG. 2.

FIG. 5 is a view illustrating another embodiment of FIG. 2.

FIG. 6 is a view illustrating a planar structure of the semiconductor package according to the embodiments of the present disclosure.

FIG. 7 is a view illustrating a cross-sectional structure of a semiconductor package according to embodiments of the present disclosure.

FIG. 8 to FIG. 14 are views illustrating a method for manufacturing a semiconductor package according to embodiments of the present disclosure.

### DETAILED DESCRIPTION

Embodiments of the present disclosure are described in detail with reference to the accompanying drawings. Specific structural or functional descriptions of the embodiments are provided as examples to describe concepts that are disclosed in the present disclosure. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

In the accompanying drawings, two directions that are parallel to the upper surface of a semiconductor chip are defined as a first direction FD and a second direction SD, respectively, and a direction that vertically protrudes from the upper surface of the semiconductor chip is defined as a third direction VD. The first direction FD and the second direction SD may be substantially perpendicular to each other. The third direction VD is a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto represent the same direction.

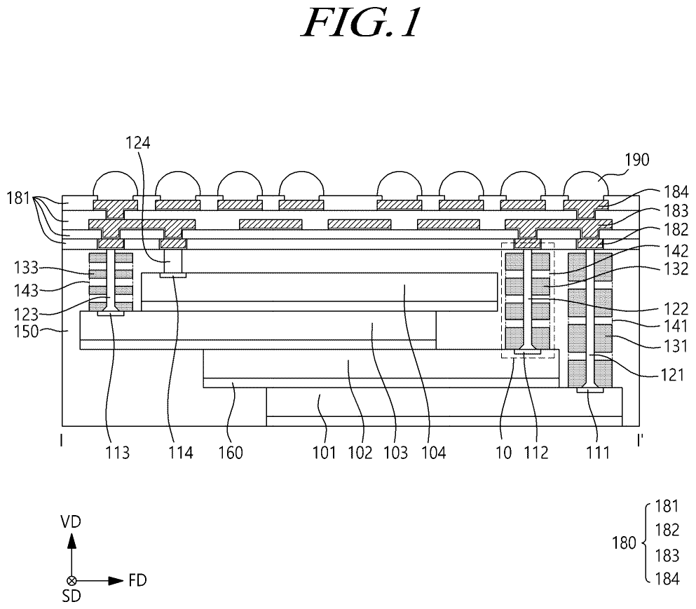

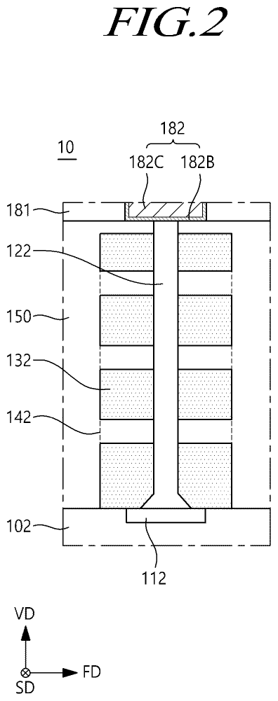

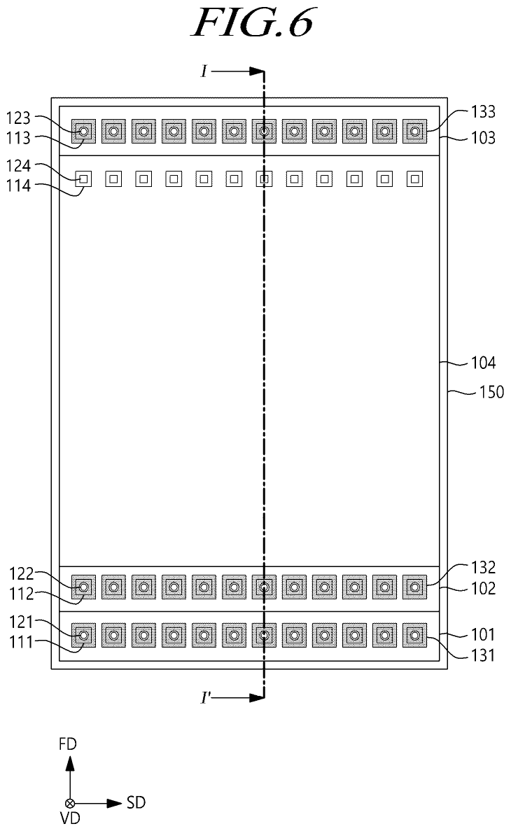

FIG. 1 is a view illustrating a cross-sectional structure of a semiconductor package according to embodiments of the present disclosure. FIG. 2 is an enlarged view of a part 10 of FIG. 1. FIG. 6 is a view illustrating a planar structure of the semiconductor package according to the embodiments of the present disclosure. FIG. 1 is a cross-sectional view taken along the cutting line I-I′ of FIG. 6.

Referring to FIG. 1 and FIG. 6, the semiconductor package according to the embodiments of the present disclosure may include semiconductor chips 101, 102, 103 and 104, connection wirings 121, 122, 123 and 124, coating layers 131, 132 and 133, an encapsulation layer 150, an adhesive layer 160, a redistribution layer 180, and an external connection terminal 190.

The semiconductor chips 101, 102, 103 and 104 may include a first semiconductor chip 101, a second semiconductor chip 102, a third semiconductor chip 103 and a fourth semiconductor chip 104. The semiconductor chips 101, 102, 103 and 104 may include memory such as volatile memory, nonvolatile memory or a combination thereof. Each of the semiconductor chips 101, 102, 103 and 104 may include dynamic random access memory (DRAM), static random access memory (SRAM), flash memory, magnetoresistive random access memory (MRAM), phase-change random access memory (PRAM), ferroelectric random access memory (FRAM), resistive random access memory (RRAM), or a combination thereof. In an embodiment, at least one of the semiconductor chips 101, 102, 103 and 104 may be a logic chip such as a controller.

The connection wirings 121, 122, 123 and 124 may include a first connection wiring 121, a second connection wiring 122, a third connection wiring 123 and a fourth connection wiring 124. The coating layers 131, 132 and 133 include a first coating layer 131, a second coating layer 132 and a third coating layer 133. The redistribution layer 180 may include a landing pad 182, an internal wiring 183, an upper pad 184 and an insulating layer 181. The insulating layer 181 may cover the landing pad 182, the internal wiring 183, and the upper pad 184.

The second semiconductor chip 102 may be offset-stacked on the first semiconductor chip 101 in the first direction FD. The third semiconductor chip 103 may be offset-stacked on the second semiconductor chip 102 in the first direction FD. The fourth semiconductor chip 104 may be offset-stacked on the third semiconductor chip 103 in the first direction FD. The fourth semiconductor chip 104 may be offset-stacked in a direction opposite to a direction in which the third semiconductor chip 103 is offset-stacked. The first semiconductor chip 101 is disposed at the bottom of the chip stack, and the fourth semiconductor chip 104 is disposed at the top of the chip stack. The adhesive layer 160 may be disposed between the semiconductor chips 101, 102, 103 and 104. However, the adhesive layer 160 may be omitted as the occasion demands in other embodiments.

The semiconductor chips 101, 102, 103 and 104 may include chip terminals 111, 112, 113 and 114, respectively. The chip terminals 111, 112, 113 and 114 may include a first chip terminal 111 of the first semiconductor chip 101, a second chip terminal 112 of the second semiconductor chip 102, a third chip terminal 113 of the third semiconductor chip 103 and a fourth chip terminal 114 of the fourth semiconductor chip 104.

Each of the chip terminals 111, 112, 113 and 114 may be disposed on one surface of a corresponding semiconductor chip of the semiconductor chips 101, 102, 103 and 104 in various ways. In an embodiment, the chip terminals 111, 112, 113 and 114 may be aligned at a constant interval from an edge of a corresponding semiconductor chip of the semiconductor chips 101, 102, 103 and 104. The respective semiconductor chips 101, 102, 103 and 104 may be arranged in a staggered manner so that a landing pad 182, an internal wiring 183, an upper pad 184 do not overlap with but expose the chip terminals 111, 112, 113 and 114 of other semiconductor chips.

The chip terminals 111, 112, 113 and 114 may include an input/output pad, a power pad and a ground pad. The chip terminals 111, 112, 113 and 114 may include conductive material such as Al, Cu, Ti, TiN, Ta, TaN, Co, Ag, Pt, Au, Sn or a combination thereof.

The connection wirings 121, 122, 123 and 124 are disposed on the chip terminals 111, 112, 113 and 114. Each of the connection wirings 121, 122, 123 and 124 is connected at a first end thereof to a corresponding chip terminal of the chip terminals 111, 112, 113 and 114. The connection wirings 121, 122, 123 and 124 include the first connection wiring 121 on the first chip terminal 111, the second connection wiring 122 on the second chip terminal 112, the third connection wiring 123 on the third chip terminal 113 and the fourth connection wiring 124 on the fourth chip terminal 114.

Each of the connection wirings 121, 122, 123 and 124 may extend vertically from a surface of a corresponding semiconductor chip among the semiconductor chips 101, 102, 103 and 104. In an embodiment, each of the connection wirings 121, 122, 123 and 124 may extend vertically on a corresponding chip terminal among the chip terminals 111, 112, 113 and 114. The uppermost end of each of the connection wirings 121, 122, 123 and 124 may be positioned higher than the upper surface of an uppermost semiconductor chip (e.g., the fourth semiconductor chip 104).

Each of the connection wirings 121, 122, 123 and 124 may include a vertical wire, a conductive pillar, a conductive bump or a combination thereof. In an embodiment, the connection wirings 121, 122, 123 and 124 may include bonding wires. In an embodiment, the connection wiring of an uppermost semiconductor chip may be a conductive bump, and the connection wirings of remaining semiconductor chips except the uppermost semiconductor chip may be bonding wires. For example, the first to third connection wirings 121, 122 and 123 of the first semiconductor chip 101, the second semiconductor chip 102 and the third semiconductor chip 103 may be bonding wires, and the fourth connection wiring 124 of the fourth semiconductor chip 104 may be a conductive bump. The connection wirings 121, 122, 123 and 124 may include Au, Ag, Cu, Al, Sn or a combination thereof.

Referring to FIG. 1 and FIG. 2, the coating layers 131, 132 and 133 are disposed on the side surfaces of connection wirings 121, 122 and 123. For example, the first coating layer 131 may be disposed on the side surface of the first connection wiring 121, the second coating layer 132 may be disposed on the side surface of the second connection wiring 122, and the third coating layer 133 may be disposed on the side surface of the third connection wiring 123. In an embodiment, each of the coating layers 131, 132 and 133 may surround the side surface of a corresponding connection wiring among the connection wirings 121, 122 and 123. In an embodiment, the coating layers 131, 132 and 133 may be cylindrical in shape. However, the embodiments are not limited thereto, and the coating layers 131, 132 and 133 may have various shapes. The upper surfaces of the coating layers 131, 132 and 133 may be positioned lower than the upper surface of the encapsulation layer 150.

The first, second, and third coating layers 131, 132, and 133 may be spaced apart from each other in the first direction FD. In an embodiment, each of the first, second, and third coating layers 131, 132 and 133 may contact the upper surface of one semiconductor chip, and may be spaced apart from the remaining semiconductor chips. For example, the first coating layer 131 may contact the upper surface of the first semiconductor chip 101, and may be spaced apart from the second semiconductor chip 102. The second coating layer 132 may contact the upper surface of the second semiconductor chip 102, and may be spaced apart from the fourth semiconductor chip 104. The third coating layer 133 may contact the upper surface of the third semiconductor chip 103, and may be spaced apart from the fourth semiconductor chip 104. The first, second, and third coating layers 131, 132 and 133 may be made of an insulating material such as, for example, ceramic.

The first, second, and third coating layers 131, 132 and 133 may include holes 141, 142 and 143, respectively. The holes 141, 142 and 143 include a first hole 141, a second hole 142 and a third hole 143. The first coating layer 131 may include the first hole 141, the second coating layer 132 may include the second hole 142, and the third coating layer 133 may include the third hole 143. FIG. 1 illustrates that the first, second, and third coating layers 131, 132, and 133 include three first holes 141, three second holes 142 and three third holes 143, respectively. However, the number of holes included in each of the coating layers 131, 132 and 133 is not limited thereto. Also, the numbers of holes included in the coating layers 131, 132 and 133, respectively, may be different from each other. For example, in an embodiment, the first coating layer 131 may have 2 first holes 141, the second coating layer 132 may have 3 second holes 142 and the third coating layer 133 may have four holes.

The interval between the first holes 141, the interval between the second holes 142 and the interval between the third holes 143 may be different from each other. For example, the interval between the first holes 141 may be larger than the interval between the second holes 142 and/or the interval between the third holes 143. However, the embodiments are not limited thereto, and the intervals between the holes 141, 142 and 143 may be different from each other depending on the numbers of the holes 141, 142 and 143 included in the coating layer 131, 132 and 133, respectively.

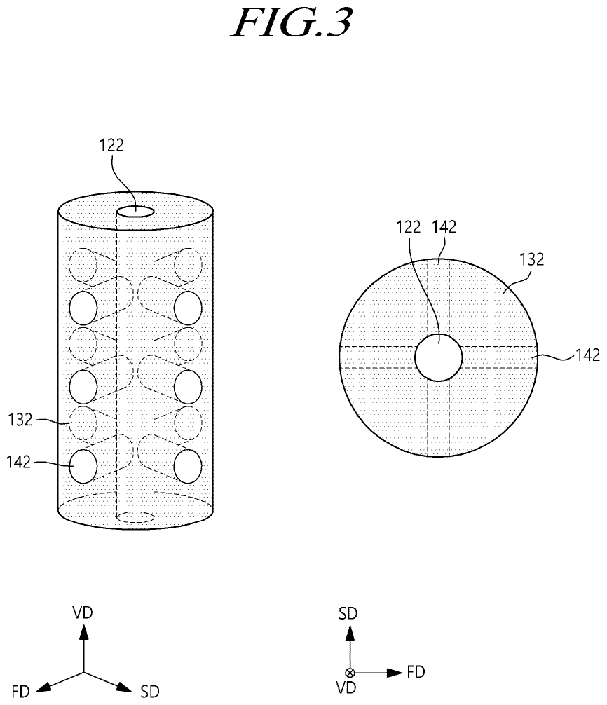

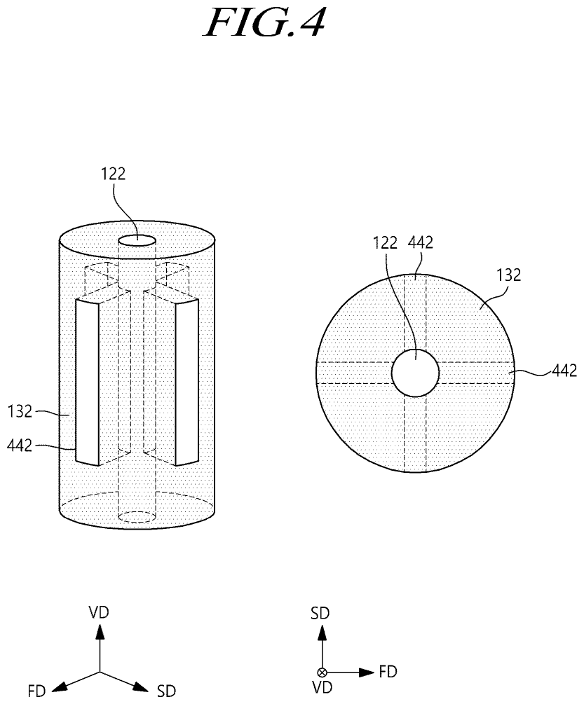

Each of the coating layers 131, 132 and 133 may expose at least a portion of the side surface of a corresponding connection wiring among the connection wirings 121, 122 and 123. In an embodiment, each of the holes 141, 142 and 143 may expose the side surface of a corresponding connection wiring among the connection wirings 121, 122 and 123. However, the embodiments are not limited thereto. In another embodiment, each of the holes 141, 142 and 143 may not expose the side surface of a corresponding connection wiring among the connection wirings 121, 122 and 123. The detailed structure of the first hole 141, the second hole 142 and the third hole 143 will be described later with reference to FIG. 3 and FIG. 4.

The encapsulation layer 150 is disposed on the outer surfaces of the coating layers 131, 132 and 133. The encapsulation layer 150 may surround the outer surfaces of the coating layers 131, 132 and 133. In an embodiment, the encapsulation layer 150 may fill the interiors of the holes 141, 142 and 143 included in the coating layers 131, 132 and 133, respectively. In an embodiment, the encapsulation layer 150 may contact the side surfaces of the first connection wiring 121, the second connection wiring 122 and the third connection wiring 123 through the first hole 141, the second hole 142 and the third hole 143, respectively. The encapsulation layer 150 may include an epoxy molding compound. This type of compound is widely used due to its excellent mechanical strength, chemical resistance, and electrical insulating properties. It provides robust protection for the underlying materials, ensuring durability and reliability in various applications.

The redistribution layer 180 is disposed on the encapsulation layer 150 and the connection wirings 121, 122, 123 and 124. The landing pad 182, the internal wiring 183 and the upper pad 184 are disposed in the insulating layer 181. The landing pad 182 may be in direct contact with a corresponding connection wiring among the connection wirings 121, 122, 123 and 124. The lower surface of the landing pad 182 may be in direct contact with the upper surface of the encapsulation layer 150. Referring to FIG. 2, the landing pad 182 may include a conductive layer 182C and a barrier layer 182B. The lower surface of the barrier layer 182B may be in direct contact with the encapsulation layer 150 and a corresponding connection wiring among the connection wirings 121, 122, 123 and 124. The barrier layer 182B may include Ti, TiN, Ta, TaN or a combination thereof.

The landing pad 182, a corresponding connection wiring among the connection wirings 121, 122, 123 and 124 and a corresponding chip terminal among the chip terminals 111, 112, 113 and 114 may overlap with each other in a vertical direction. In an embodiment, a plurality of landing pads 182 may be disposed in the insulating layer 181. Each of the plurality of landing pads 182 may vertically overlap with a corresponding connection wiring among the connection wirings 121, 122, 123 and 124. Each of the connection wirings 121, 122, 123 and 124 may vertically overlap with a corresponding chip terminal among the chip terminals 111, 112, 113 and 114.

The upper pad 184 may be electrically connected to the landing pad 182 through the internal wiring 183. The external connection terminal 190 may be disposed on the upper pad 184. External connection terminals 190 may be electrically connected to internal circuits of the semiconductor chips 101, 102, 103 and 104 through upper pads 184, internal wirings 183, landing pads 182, the connection wirings 121, 122, 123 and 124 and the chip terminals 111, 112, 113 and 114.

FIG. 3 and FIG. 4 are views each illustrating the three-dimensional structure and planar structure of a part of FIG. 2. Hereinbelow, the second coating layer 132 that surrounds the second connection wiring 122 will be described as an example.

Referring to FIG. 3, the second coating layer 132 includes at least one second hole 142. The second hole 142 may extend from the outer surface of the second coating layer 132 toward the second connection wiring 122 in the first direction FD. In an embodiment, the second hole 142 may pass through the second coating layer 132 to expose the side surface of the second connection wiring 122. However, the embodiments are not limited thereto, and the second hole 142 might not pass through the second coating layer 132. For example, the second hole 142 may have a shape that is recessed from the outer surface of the second coating layer 132 toward the second connection wiring 122 in the first direction FD but may not expose the side surface of the second connection wiring 122.

In an embodiment, the second hole 142 may be formed to have a circular shape on the outer surface of the second coating layer 132. However, the embodiments are not limited thereto, and the second hole 142 may be formed to have various shapes on the outer surface of the second coating layer 132.

Referring to FIG. 4, the second coating layer 132 includes at least one second hole 442. The second hole 442 may extend from the outer surface of the second coating layer 132 toward the second connection wiring 122 in the first direction FD. In an embodiment, the second hole 442 may pass through the second coating layer 132 to expose the side surface of the second connection wiring 122. In another embodiment, the second hole 442 might not expose the side surface of the second connection wiring 122.

The second hole 442 may be formed to have a rectangular shape on the outer surface of the second coating layer 132. The second hole 442 may extend in the vertical direction. Besides, the second hole 442 may have various sizes and shapes, and the size and shape of the second hole 442 are not limited to the embodiments described above.

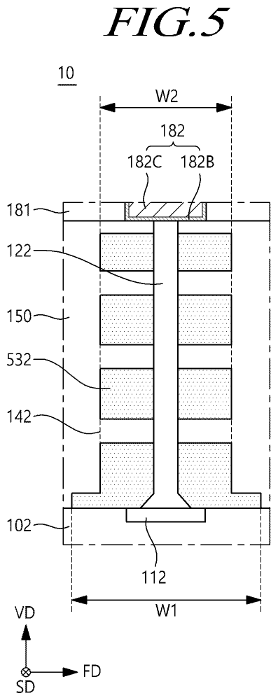

FIG. 5 is a view illustrating another embodiment of FIG. 2.

Referring to FIG. 5, a second coating layer 532 may surround the side surface of the second connection wiring 122. The lower surface of the second coating layer 532 may contact the upper surface of the second semiconductor chip 102.

In an embodiment, a width W1 of the lower surface of the second coating layer 532 may be greater than a width W2 of the upper surface of the second coating layer 532. Because the lower surface of the second coating layer 532 has a wider width than the upper surface of the second coating layer 532, the second connection wiring 122 may be effectively prevented from bending or shaking in a subsequent process of forming the encapsulation layer 150.

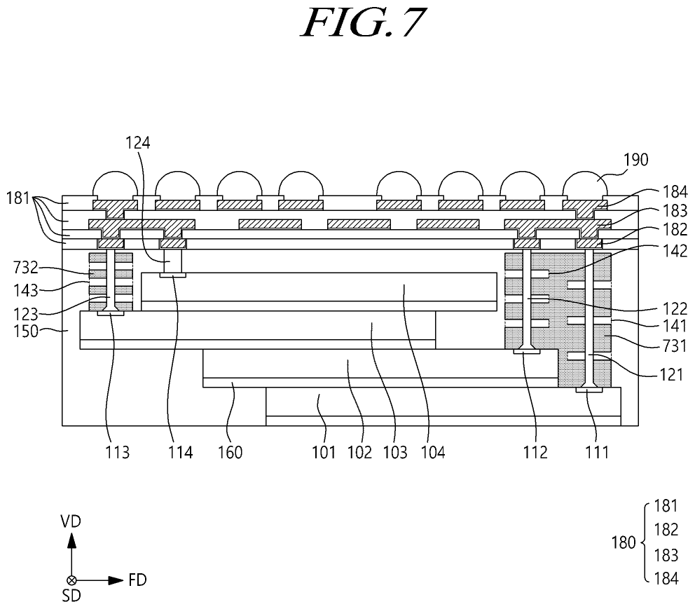

FIG. 7 is a view illustrating a cross-sectional structure of a semiconductor package according to embodiments of the present disclosure.

Referring to FIG. 7, the semiconductor package according to embodiments of the present disclosure may include semiconductor chips 101, 102, 103 and 104, connection wirings 121, 122, 123 and 124, coating layers 731 and 732, an encapsulation layer 150, an adhesive layer 160, a redistribution layer 180, and an external connection terminal 190. The coating layers 731 and 732 include a first coating layer 731 and a second coating layer 732.

The first coating layer 731 may surround the side surfaces of the first connection wiring 121 and the second connection wiring 122. The second coating layer 732 may surround the side surface of the third connection wiring 123. The first coating layer 731 may contact the upper surface of the first semiconductor chip 101 and the side surface and upper surface of the second semiconductor chip 102. The second coating layer 732 may be spaced apart from the fourth semiconductor chip 104 while contacting the upper surface of the third semiconductor chip 103.

The first coating layer 731 may include at least one first hole 141 and at least one second hole 142. At least one of first holes 141 and at least one of second holes 142 may be disposed between the first connection wiring 121 and the second connection wiring 122. The first hole 141 and the second hole 142 disposed between the first connection wiring 121 and the second connection wiring 122 may be surrounded by the first coating layer 731.

The encapsulation layer 150 may fill at least a portion of the first hole 141 and the second hole 142 included in the first coating layer 731. In an embodiment, the encapsulation layer 150 may not fill the first hole 141 that is positioned between the first connection wiring 121 and the second connection wiring 122 and the second hole 142 that is positioned between the first connection wiring 121 and the second connection wiring 122.

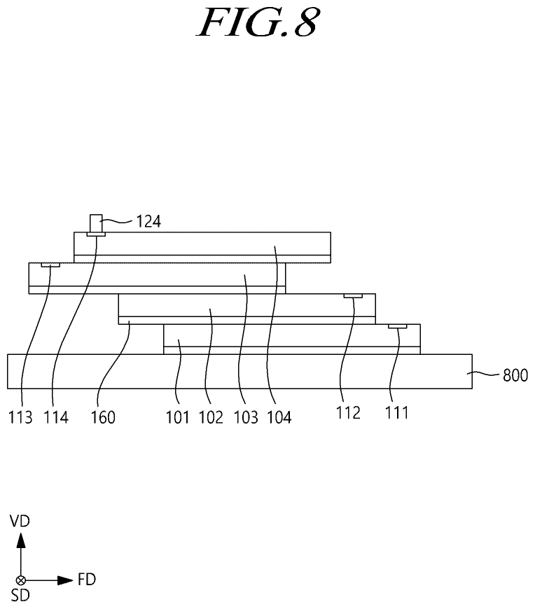

FIG. 8 to FIG. 14 are views illustrating a method for manufacturing a semiconductor package according to embodiments of the present disclosure.

Referring to FIG. 8, the method for manufacturing a semiconductor package according to an embodiment of the present disclosure includes sequentially stacking a first semiconductor chip 101, a second semiconductor chip 102, a third semiconductor chip 103 and a fourth semiconductor chip 104 on a carrier 800. An adhesive layer 160 may be formed on the semiconductor chips 101, 102, 103 and 104. The adhesive layer 160 may be disposed between adjacent semiconductor chips separating them. In an embodiment, the adhesive layer 160 may be omitted.

Chip terminals 111, 112, 113 and 114 may be formed on the upper surfaces of the semiconductor chips 101, 102, 103 and 104. For example, chip terminal 111 may be formed on the upper surface of the semiconductor chip 101, chip terminal 112 may be formed on the upper surface of the semiconductor chip 102, chip terminal 113 may be formed on the upper surface of the semiconductor chip 103, and chip terminal 114 may be formed on the upper surface of the semiconductor chip 104. More specifically, chip terminal 111 may be formed on an edge portion of the upper surface of the semiconductor chip 101 that is not overlapped by the adjacent semiconductor chip 102. Likewise, chip terminal 112 may be formed on an edge portion of the upper surface of the semiconductor chip 102 that is not covered by the adjacent semiconductor chip 103. Also, chip terminal 113 may be formed on an edge portion of the upper surface of the semiconductor chip 103 that is not overlapped by the adjacent semiconductor chip 104. Finally, chip terminal 114 may be formed on an upper edge portion of the semiconductor chip 104 that is proximate to the upper edge portion of the semiconductor chip 103 on which the chip terminal 113 is formed.

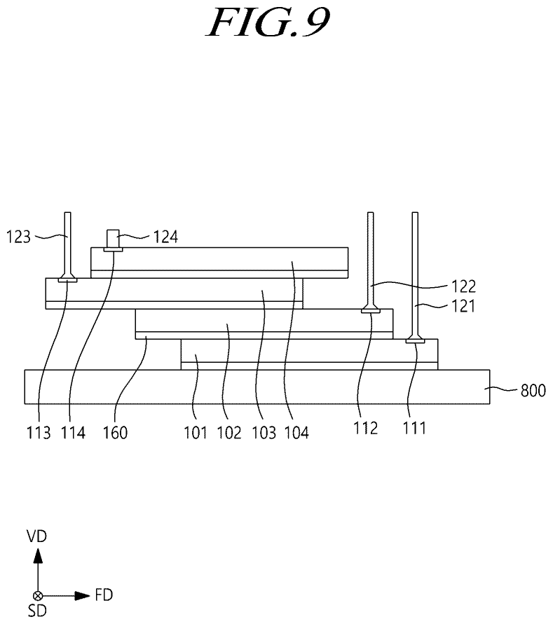

Referring to FIG. 9, a first connection wiring 121 is formed on the first chip terminal 111 of the first semiconductor chip 101, a second connection wiring 122 is formed on the second chip terminal 112 of the second semiconductor chip 102, and a third connection wiring 123 is formed on the third chip terminal 113 of the third semiconductor chip 103. One ends of the first connection wiring 121, the second connection wiring 122 and the third connection wiring 123 are connected to the first semiconductor chip 101, the second semiconductor chip 102 and the third semiconductor chip 103, respectively. The first connection wiring 121, the second connection wiring 122 and the third connection wiring 123 may have different lengths in the vertical direction VD so that their top (or uppermost) respective surfaces are aligned. A fourth connection wiring 124 may be formed on the fourth chip terminal 114. The fourth connection wiring may be wider but shorter than the first, second, and third wirings 121, 122, and 123 so that the top (or uppermost surface) of the fourth wiring 124 in the vertical direction may be lower than the uppermost surfaces of the first, second, and third wirings 121, 122, and 123.

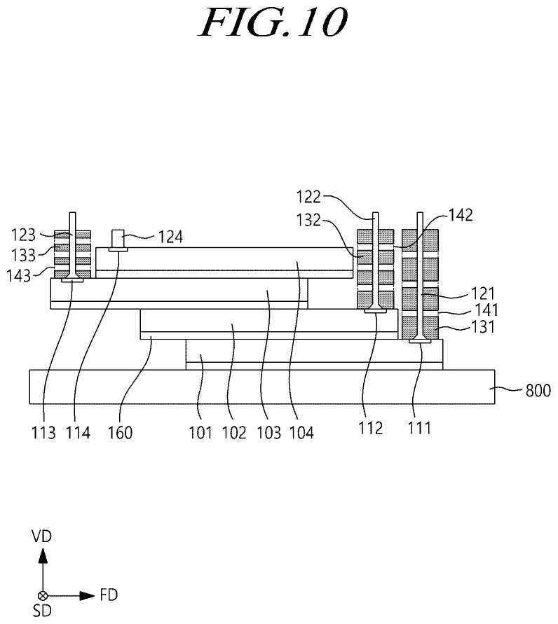

Referring to FIG. 10, a first coating layer 131 is formed to surround the side surface of the first connection wiring 121, a second coating layer 132 is formed to surround the side surface of the second connection wiring 122, and a third coating layer 133 is formed to surround the side surface of the third connection wiring 123. In an embodiment, the first, second, and third coating layers 131, 132, and 133 may be formed in different process steps. For example, the first coating layer 131 may be formed first, and then, the second coating layer 132 may be formed, followed by the third coating layer 133. In another embodiment, the first coating layer 131 and the second coating layer 132 may be formed simultaneously, and then after the first coating layer 131 and the second coating layer 132 are formed simultaneously, the third coating layer 133 may be formed.

The first, second, and third coating layers 131, 132, and 133 may include one or more holes 141, 142 and 143, respectively. In an embodiment, a process of forming each of the first, second, and third coating layers 131, 132, and 133 may include a process of injecting an insulating material such as, for example, a ceramic material including a hole from the upper surface toward the lower surface of each of the first connection wiring 121, the second connection wiring 122 and the third connection wiring 123.

Each of the first, second, and third coating layers 131, 132, and 133 may expose the top surface and an upper portion of the side surface of each of the first connection wiring 121, the second connection wiring 122 and the third connection wiring 123 that is adjacent to their top surface. Also, each of the first, second, and third coating layers 131, 132, and 133 may have one or more horizontal holes that expose another portion or portions of the side surface of each of the first connection wiring 121, the second connection wiring 122 and the third connection wiring 123.

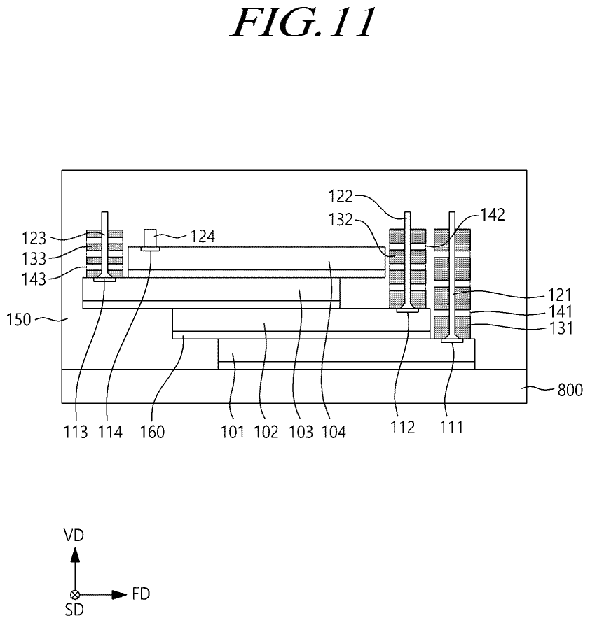

Referring to FIG. 11, an encapsulation layer 150 that covers the semiconductor chips 101, 102, 103 and 104 may be formed on the carrier 800. In an embodiment, the encapsulation layer 150 may be formed to completely cover the side surfaces and upper surfaces of the semiconductor chips 101, 102, 103 and 104, the side surfaces and upper surfaces of the coating layers 131, 132 and 133, and the connection wirings 121, 122, 123 and 124. The encapsulation layer 150 may be formed using a molding process.

The encapsulation layer 150 may be formed to fill the interiors of the holes 141, 142 and 143 included in the coating layers 131, 132 and 133, respectively. In an embodiment, the encapsulation layer 150 may contact the side surfaces of the connection wirings 121, 122 and 123 while filling the interiors of the holes 141, 142 and 143.

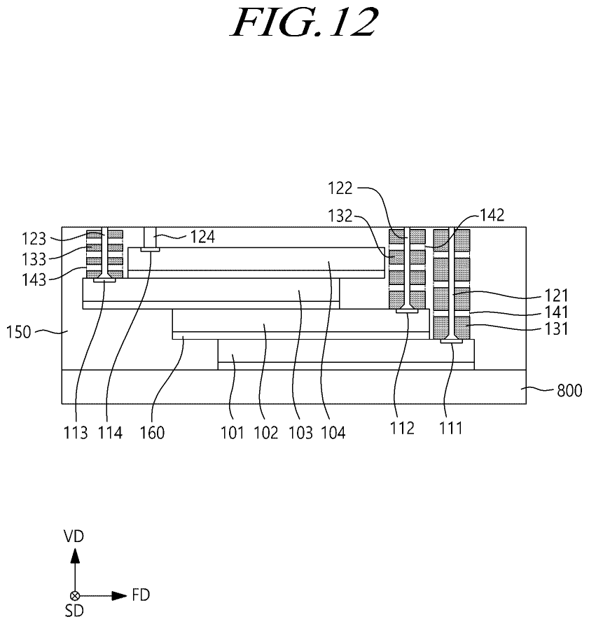

Referring to FIG. 12, by removing the upper portions of the encapsulation layer 150 and upper portions of the connection wirings 121, 122, 123 and 124, the upper surfaces of the encapsulation layer 150 and the connection wirings 121, 122, 123 and 124 may be exposed on substantially the same plane. A process of removing the upper portions of the encapsulation layer 150 and the connection wirings 121, 122, 123 and 124 may include a grinding process.

In an embodiment, the upper surfaces of the coating layers 131, 132 and 133 may be positioned lower than the upper surface of the encapsulation layer 150.

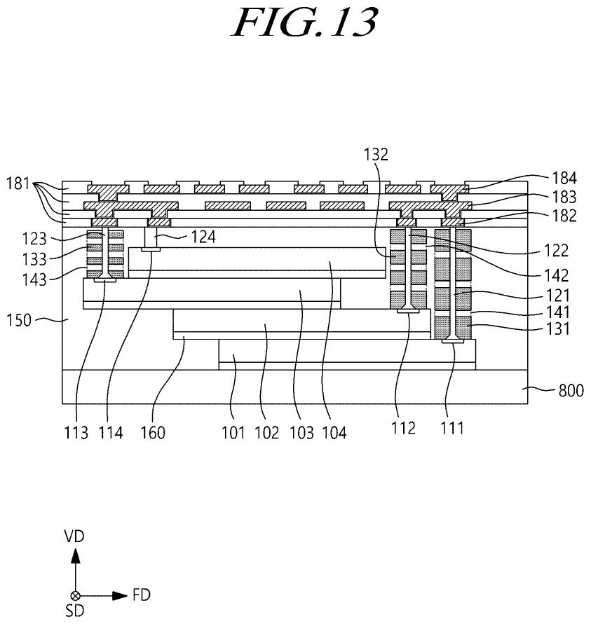

Referring to FIG. 13, landing pads 182 may be formed on the connection wirings 121, 122, 123 and 124 and the encapsulation layer 150. Internal wirings 183 and upper pads 184 may be formed on the landing pads 182. An insulating layer 181 that covers the landing pads 182, the internal wirings 183 and the upper pads 184 may also be formed.

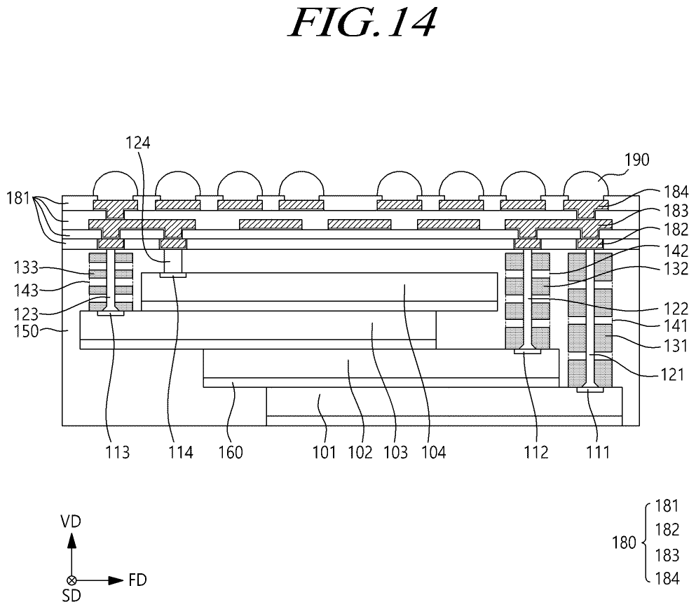

Referring to FIG. 14, external connection terminals 190 may be formed on the upper pads 184. The external connection terminals 190 contact the upper surfaces of the upper pads 184. Each external connection terminal 190 may be formed to overlap with a corresponding upper pad among the upper pads 184. The carrier 800 of FIG. 13 may be removed.

Referring again to FIG. 1, the coating layers 131, 132 and 133 may surround the side surfaces of the connection wirings 121, 122 and 123, respectively. The coating layers 131, 132 and 133 may include one or more holes 141, 142 and 143, respectively, and the encapsulation layer 150 may be formed to fill the interiors of the holes 141, 142 and 143.

A process of forming the encapsulation layer 150 may be a process of completely filling the spaces between the semiconductor chips 101, 102, 103 and 104 and areas around the connection wirings 121, 122 and 123. In the course of forming the encapsulation layer 150, the connection wirings 121, 122 and 123 may bend or shake. This may cause the connection wirings 121, 122 and 123 to deviate from areas where the landing pads 182 are disposed, in a subsequent process of forming the redistribution layer 180. In this case, a problem may arise in the electrical connection between the semiconductor chips 101, 102, 103 and 104 and external devices.

However, according to embodiments of the present disclosure, because the coating layers 131, 132 and 133 are formed to surround the connection wirings 121, 122 and 123, the connection wirings 121, 122 and 123 may not bend or shake in the course of forming the encapsulation layer 150. Moreover, forming the holes 141, 142 and 143 in the coating layers 131, 132 and 133, which are filled at least partially with the encapsulation layer 150 may more effectively prevent bending or shaking of the connection wirings 121, 122, and 123 when forming the encapsulation layer 150. Therefore, the connection wirings 121, 122 and 123 may be well aligned with their corresponding landing pads 182, and accordingly, the electrical connection characteristics between the semiconductor chips 101, 102, 103 and 104 and the external devices may be improved.

While detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. Also, all changes within the meaning and range of equivalency of the claims are included within their scope. Furthermore, the embodiments may be combined to form additional embodiments.

What is claimed is:

1. A semiconductor package comprising:
a semiconductor chip;
a bonding wire having one end that contacts an upper surface of the semiconductor chip;
a landing pad contacting the other end of the bonding wire, and facing the upper surface of the semiconductor chip;
a coating layer disposed between the landing pad and the semiconductor chip, surrounding a side surface of the bonding wire, and including a hole; and
an encapsulation layer surrounding the coating layer.

2. The semiconductor package according to claim 1, wherein the encapsulation layer fills an interior of the hole.

3. The semiconductor package according to claim 1, wherein the encapsulation layer contacts the side surface of the bonding wire through the hole.

4. The semiconductor package according to claim 1, wherein the hole extends from an outer surface of the coating layer to the side surface of the bonding wire.

5. The semiconductor package according to claim 1, wherein, in a direction perpendicular to the upper surface of the semiconductor chip, a length of the coating layer is shorter than a length of the bonding wire.

6. The semiconductor package according to claim 1, wherein
a lower surface of the coating layer has a first width, and an upper surface of the coating layer has a second width, and
the first width is greater than the second width.

7. The semiconductor package according to claim 1, wherein
the bonding wire includes first and second bonding wires that are connected to different semiconductor chips, and
wherein a coating layer that surrounds a side surface of the first bonding wire is spaced apart from a coating layer that surrounds a side surface of the second bonding wire.

8. The semiconductor package according to claim 1, wherein the coating layer corresponds to each bonding wire.

9. The semiconductor package according to claim 1, wherein the encapsulation layer covers the upper surface of the semiconductor chip.

10. A semiconductor package comprising:
a first semiconductor chip;
a second semiconductor chip positioned on the first semiconductor chip;
a first bonding wire connected to the first semiconductor chip;
a second bonding wire connected to the second semiconductor chip;
a first coating layer surrounding a side surface of the first bonding wire, and including a first hole;
a second coating layer surrounding a side surface of the second bonding wire, including a second hole, and spaced apart from the first coating layer; and
an encapsulation layer surrounding the first coating layer and the second coating layer, and filling interiors of the first hole and the second hole.

11. The semiconductor package according to claim 10, wherein the encapsulation layer contacts the side surface of the first bonding wire through the first hole and the side surface of the second bonding wire through the second hole.

12. The semiconductor package according to claim 10, wherein, in a direction perpendicular to an upper surface of the first semiconductor chip or the second semiconductor chip, lengths of the first coating layer and the second coating layer are shorter than lengths of the first bonding wire and the second bonding wire, respectively.

13. The semiconductor package according to claim 10, wherein, in a direction perpendicular to an upper surface of the first semiconductor chip or the second semiconductor chip, a length of the first coating layer is longer than a length of the second coating layer.

14. The semiconductor package according to claim 10, wherein the second semiconductor chip is stacked directly on top of the first semiconductor chip.

15. The semiconductor package according to claim 10, wherein
a lower surface of the first coating layer has a first width, and an upper surface of the first coating layer has a second width, and
the first width is greater than the second width.

16. The semiconductor package according to claim 10, wherein the encapsulation layer covers upper surfaces of the first and second semiconductor chips.

17. A method for manufacturing a semiconductor package, the method comprising:
connecting one end of a bonding wire to a semiconductor chip, and aligning the bonding wire in a direction perpendicular to an upper surface of the semiconductor chip;
forming a coating layer that surrounds a side surface of the bonding wire and includes a hole; and
forming an encapsulation layer to surround a side surface of the coating layer and fill an interior of the hole.

18. The method according to claim 17, wherein the encapsulation layer contacts the side surface of the bonding wire through the hole.

19. The method according to claim 17,
wherein the bonding wire includes first and second bonding wires that are spaced apart from each other, and
wherein forming the coating layer comprises:
forming a first coating layer that surrounds a side surface of the first bonding wire and includes a first hole; and
forming a second coating layer that surrounds a side surface of the second bonding wire and includes a second hole.

20. The method according to claim 19, wherein the first coating layer and the second coating layer are spaced apart from each other.
